(19) United States
(12) Patent Application Publication
(10) Pub. No.: US 2024/0243108 A1
(43) Pub. Date: Jul. 18, 2024

(54) ELECTRONIC DEVICE AND METHOD FOR FORMING THE SAME

(71) Applicant: InnoLux Corporation, Miao-Li County (TW)

(72) Inventors: Jui-Jen YUEH, Miao-Li County (TW); Kuan-Feng LEE, Miao-Li County (TW); Jia-Yuan CHEN, Miao-Li County (TW); Cheng-Chi WANG, Miao-Li County (TW)

(21) Appl. No.: 18/401,894

(22) Filed: Jan. 2, 2024

(30) Foreign Application Priority Data
Jan. 16, 2023 (CN) 202310074864.7

(51) Int. Cl. H01L 25/075; H01L 23/00; H01L 33/54; H01L 33/60; H01L 33/62

(52) U.S. Cl. CPC H01L 25/0753; H01L 33/54; H01L 33/60; H01L 24/13; H01L 24/16; H01L 33/62; H01L 2224/13105; H01L 2224/13111; H01L 2224/13124; H01L 2224/13139; H01L 2224/13144; H01L 2224/13147; H01L 2224/13166; H01L 2224/16227; H01L 2924/12041; H01L 2933/005; H01L 2933/0066

(57) ABSTRACT

An electronic device is provided. The electronic device includes a substrate, a plurality of light-emitting elements, and a protective layer. The substrate includes a connecting element. The plurality of light-emitting elements is disposed on the substrate. The protective layer is disposed on the substrate and includes an opaque layer and a transparent layer. The opaque layer has a plurality of openings. At least a portion of the transparent layer is disposed in the openings and covers the respective light-emitting elements. The protective layer surrounds the connecting element.

### CROSS REFERENCE TO RELATED APPLICATIONS

This application claims priority of China Patent Application No. 202310074864.7 filed on Jan. 16, 2023, the entirety of which is incorporated by reference herein.

### BACKGROUND

### Technical Field

The present disclosure relates to electronic devices, and in particular it relates to an electronic device that includes an opaque layer.

### Description of the Related Art

With the continuous advancements being made in the application of electronic devices, the development of display technology is also changing with each passing day. However, in the face of different manufacturing and technical conditions, the requirements for the structure and quality of electronic devices are getting higher and higher, so that the manufacturing of electronic devices faces different challenges.

The light-emitting diode modules manufactured using the prior art are thick, and the integration density of circuits is low. Therefore, it is impossible to accommodate more light-emitting diode elements in an electronic device of the same size. In addition, since a large amount of light-emitting diodes that are not modularized are transferred in the prior art, a large number of transfers is required, which increases the time and cost of manufacturing the electronic device. Furthermore, the light-emitting diodes in traditional electronic devices are sealed with a single packaging material, and the connecting element is not used for modularization, so that the repair cost of individual light-emitting diodes is relatively high and more complicated.

To sum up, although existing electronic devices have been generally adequate for their intended purposes, they have not been entirely satisfactory in all respects. For example, how to increase integration density while reducing the manufacturing cost of electronic devices is still a research topic in the industry. Therefore, the research and development of electronic devices requires continuous updates and adjustments to solve various problems faced by the manufacturers of electronic devices.

### BRIEF SUMMARY

The present disclosure provides an electronic device. The electronic device includes a substrate, a plurality of light-emitting elements, and a protective layer. The substrate includes a connecting element. The plurality of light-emitting elements is disposed on the substrate. The protective layer is disposed on the substrate and includes an opaque layer and a transparent layer. The opaque layer has a plurality of openings. At least a portion of the transparent layer is disposed in the openings and covers the respective light-emitting elements. The protective layer surrounds the connecting element.

The present disclosure provides a method for forming an electronic device. The method includes forming a plurality of light-emitting elements on a substrate including a connecting element. The method also includes forming a protective layer on the substrate. The protective layer includes an opaque layer and a transparent layer. The opaque layer has a plurality of openings. At least a portion of the transparent layer is disposed in the openings and covers the respective light-emitting elements. The protective layer surrounds the connecting element.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion

FIG. 1A illustrates a cross-sectional view of an electronic device corresponding to a section line AA′ of FIG. 1B, in accordance with some embodiments of the present disclosure.

FIG. 1B illustrates a top view of the electronic device corresponding to FIG. 1A, in accordance with some embodiments of the present disclosure.

FIG. 1C illustrates a cross-sectional view of an electronic device, in accordance with some embodiments of the present disclosure.

FIG. 2A illustrates a cross-sectional view of an electronic device corresponding to a section line BB′ of FIG. 2B, in accordance with some embodiments of the present disclosure.

FIG. 2B illustrates a top view of the electronic device corresponding to FIG. 2A, in accordance with some embodiments of the present disclosure.

FIG. 3 illustrates a cross-sectional view of an electronic device, in accordance with some embodiments of the present disclosure.

FIG. 4 illustrates a cross-sectional view of an electronic device, in accordance with some other embodiments of the present disclosure.

FIGS. 5A-5F illustrate cross-sectional views of an electronic device in various stages of a manufacturing process, in accordance with some embodiments of the present disclosure.

FIGS. 6A-6C illustrate cross-sectional views of an electronic device in various stages of a manufacturing process, in accordance with some other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Unless otherwise defined, all terms (including technical and scientific terms) used herein have the same meaning as commonly understood by those skilled in the art to which this disclosure belongs. It can be understood that these terms, such as those defined in commonly used dictionaries, should be interpreted as having meanings consistent with the background or context of the related technology and the present disclosure, and should not be interpreted in an idealized or overly formal manner, unless otherwise specified in the disclosed embodiments.

The terms “about”, “approximately”, and “substantially” used herein generally refer to a given value or a range within 20 percent, preferably within 10 percent, and more preferably within 5 percent, within 3 percent, within 2 percent, within 1 percent, or within 0.5 percent. It should be noted that the amounts provided in the specification are approximate amounts, which means that even “about”, “approximate”, or “substantially” are not specified, the meanings of “about”, “approximate”, or “substantially” are still implied.

It should be understood that the following embodiments can replace, combine, and reorganize features in several different embodiments to complete other embodiments without departing from the spirit of the present disclosure. As long as the features of the various embodiments do not violate the spirit of the invention or conflict, they can be recombined and used arbitrarily.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

The term “substantially” as used herein indicates the value of a given quantity that can vary based on a particular technology node associated with the subject semiconductor device. In some embodiments, based on the particular technology node, the term “substantially” can indicate a value of a given quantity that varies within, for example, +10% of a target (or intended) value.

In the present disclosure, the measurement methods of length, thickness, width, height, distance and area may be completed by optical microscope (OM), electron microscope (such as scanning electron microscope (SEM)) or completed by other methods, but it is not limited thereto.

It should be understood that the electronic device of the present disclosure may include a power module, a semiconductor device, a semiconductor packaging device, a display device, a radar device, a LIDAR device, an antenna device, a touch display device, a curved display device or a non-rectangular display device (free shape display), but not limited to this. The electronic device may be a bendable or flexible electronic device. The electronic device may include, for example, but not limited to, light-emitting diodes, liquid crystals, fluorescence, phosphors, other suitable display media, or a combination thereof. The light-emitting diodes may include, for example, organic light-emitting diodes (OLEDs), inorganic light-emitting diodes (LEDs), mini-light-emitting diodes (mini LEDs), micro-light-emitting diodes (micro-LEDs), quantum dots (QDs) light-emitting diodes (such as QLEDs and QDLEDs), other suitable materials or an arbitrary combination thereof, but not limited to. The display device may include, for example, but is not limited to, a tiled display device. The concepts or principles of the present disclosure may also be applied to a non-self-luminous liquid crystal display (LCD), but are not limited thereto.

The antenna device may be, for example, a 5G antenna, a Beyond-5G antenna, a 6G antenna, a liquid crystal antenna, a phased array antenna, a lower orbit satellite antenna, or other kinds of antennas, but is not limited thereto. The antenna device may include, for example, but is not limited to, a tiled antenna device. It should be noted that, the electronic device may be any arrangement or combination of the foregoing, but it is not limited to this. In addition, the shape of the electronic device may be rectangular, circular, polygonal, a shape with curved edges, or other suitable shapes. The electronic device may have peripheral systems such as a driving system, a control system, a light source system, a shelf system, or the like to support the display device, the antenna device or the tiled device. The electronic device of the present disclosure may be, for example, a display device, but is not limited thereto.

The manufacturing process of the electronic device of the present disclosure may for example be applied to the wafer-level package (WLP) process or the panel-level package (PLP) process. The WLP process or the PLP process includes the chip-first process or the chip-last process, but not limited thereto. The electronic device may include the system on a chip (SoC), the system in a package (SiP), the antenna in package (AiP) or combinations of the above-mentioned device, but not limited thereto.

The present disclosure provides an electronic device and a method for forming the same, wherein the connecting element is integrated into the electronic device and the light-emitting elements are modularly packaged with both transparent and opaque materials. By carrying out mass transfer of the light-emitting elements packaged by modularization, the number of transfers can be reduced, or the manufacturing cost and time of the electronic device can be reduced. In addition, due to the modularization of each light-emitting element by using the connecting element, the repair of failure of individual light-emitting elements becomes easier. Compared with conventional electronic devices sealed with a single encapsulation material, the electronic device of the present disclosure can reduce the manufacturing cost of the electronic device or increase the integration density.

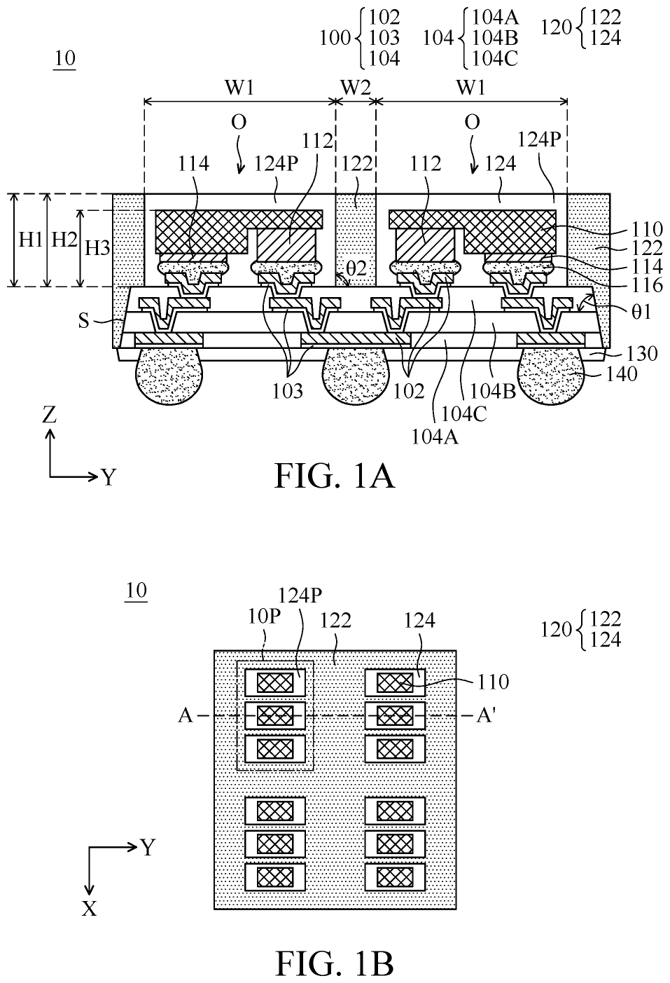

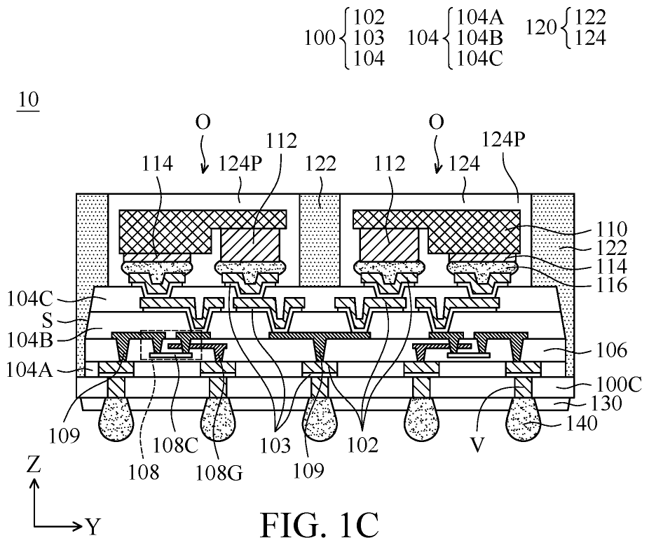

FIGS. 1A and 1B illustrate a cross-sectional view and a top view of an electronic device respectively, in accordance with some embodiments of the present disclosure, wherein FIG. 1A is the cross-sectional view on the direction of the section line AA′ of FIG. 1B. Referring to FIG. 1A, an electronic device 10 may include a substrate 100, a plurality of light-emitting elements 110, and a protective layer 120. The substrate 100 includes a connecting element. The light-emitting elements 110 may be disposed on the substrate 100. The protective layer 120 may be disposed on the substrate 100. According to some embodiments, the protective layer 120 may include an opaque layer 122 and a transparent layer 124. The opaque layer 122 may have a plurality of openings O. The transparent layer 124 may cover the light-emitting elements 110 and has a plurality of transparent portions 124P disposed in the openings O. The protective layer 120 surrounds the connecting element. According to some embodiments, the opaque layer 122 can absorb the light emitted by the light-emitting elements 110 or absorb ambient light, making it difficult for light to pass through, thereby improving display quality, but it is not limited thereto. According to some embodiments, the opaque layer 122 can reflect the light emitted by the light-emitting elements 110, so that the light emitted by the light-emitting elements 110 can pass through the transparent layer 124 to improve light use efficiency, but it is not limited thereto. According to some embodiments, other suitable electronic elements may replace a portion of positions of the light-emitting elements, such as diodes, chips, photo sensors, SMD elements, but not limited thereto.

As shown in FIG. 1A, the substrate 100 may include circuit layers 102 electrically connected to each other and an insulating structure 104 surrounding the circuit layers 102. According to some embodiments, the connecting element of the substrate 100 includes a structure in which at least one insulating layer and at least one circuit layer are alternately stacked. So as to said, the connecting element may be a redistribution layer (RDL) structure to redistribute the wires and/or increase the fan-out area of the wires, or the electronic elements may be electrically connected to each other through the connecting element. According to some embodiments, the substrate 100 may be a circuit board, but not limited to. According to some embodiments, the side surfaces and the bottom surface of each of the insulating layers 104A, 104B, and 104C have an angle θ1, wherein the angle θ1 is greater than or equal to 15 degrees and less than or equal to 50 degrees, but it is not limited thereto. Through the above-mentioned design, the bonding ability between layers can be improved or the thickness of the connecting element can be reduced, thereby improving the stress distribution, or improving the reliability of the electronic device 10, but it is not limited thereto. According to some embodiments, the substrate 100 may include a connecting element disposed on a carrier board (such as a carrier board 100C including through vias V shown in FIG. 1C), but is not limited thereto. The carrier board may include transparent or opaque organic or inorganic materials, and may also include hard or flexible materials. The organic material may include polyimide (PI), polycarbonate (PC), polyethylene terephthalate (PET), liquid crystal polymer (LCP), other known suitable materials or a combination thereof, but the disclosure is not limited thereto. The inorganic material may include dielectric material or metal material, but the present disclosure is not limited thereto. The hard material may be, for example, glass, quartz, sapphire, ceramic or plastic, or any suitable material. Here, the term “flexible material” refers to a material that may be curved, bent, folded, rolled, flexible, stretched, and/or other similar deformations, which represents at least one of the above-mentioned possible deformation manners. Examples of flexible materials may include one of the above-mentioned organic materials, but the flexible materials referred to in the present disclosure are not limited to the above-mentioned materials, and the term “flexibility” is not limited to the above-mentioned deformation manners. The circuit layers 102 may be electrically connected to the light-emitting elements 110. It should be noted that the term “surrounding” in the present disclosure means that the first element may contact the side surfaces of the second element in a cross-sectional view. For example, as shown in FIG. 1A, the circuit layers 102 is at least partially disposed in the insulating structure 104, and the insulating structure 104 may contact the side surfaces of the circuit layers 102.

Although three circuit layers 102 electrically connected to each other are shown in FIG. 1A, the present disclosure is not limited thereto. In other embodiments, the substrate 100 may also include less than three layers or more than three layers of the circuit layers 102. That is, those with ordinary knowledge may determine the number and configuration of the circuit layers 102 according to the design requirements of the electronic device. In addition, it should be understood that the Z direction in FIG. 1A may refer to the direction in which the insulating layers 104A, 104B and 104C in the insulating structure 104 and the circuit layers 102 are alternately stacked, and the Z direction may also be referred to as the normal direction of the electronic device 10.

The material of the circuit layers 102 may include, for example, copper (Cu), tin (Sn), nickel (Ni), silver (Ag), gold (Au), titanium (Ti), molybdenum (Mo), tungsten (W), aluminum (Al), other suitable conductive materials, or a combination thereof, but it is not limited thereto.

Depending on the number and configuration of the circuit layers 102, the insulating structure 104 may include a single material or multiple layers of similar or different materials, which is not limited in the present disclosure. For example, as shown in FIG. 1A, the insulating structure 104 may include three insulating layers 104A, 104B, and 104C stacked in sequence. The material of the insulating structure 104 may include polyimide PI), polybenzoxazole (PBO), benzocyclobutene (BCB), build-up material ABF (Ajinomoto Build-up Film), epoxy resin, other suitable materials, or a combination thereof, but it is not limited thereto. The insulating structure may include filling particles, and the material of the filling particles may be, for example, silicon oxide, aluminum oxide, silicon carbide, combinations thereof, or other suitable materials.

In some embodiments, the substrate 100 further includes a seed layer 103 under each circuit layers 102, but it is not limited thereto. The material of the seed layer 103 includes copper (Cu), tin (Sn), nickel (Ni), silver (Ag), gold (Au), titanium (Ti), molybdenum (Mo), tungsten (W), aluminum (Al), other suitable conductive materials, or a combination thereof, but it is not limited thereto.

In some embodiments, the substrate 100 further includes multiple alignment components disposed on the substrate 100, and at least one of the alignment components is electrically connected to the light-emitting elements 110. For example, as shown in FIG. 1A, the uppermost circuit layer 102 may be multiple alignment components. The alignment components may have grooves facing the light-emitting elements 110. The alignment components can be used to align the light-emitting elements 110 to designated positions above the circuit layers 102. In addition, by increasing the lateral stress that the light-emitting elements 110 can bear, the grooves of the alignment components can be used to strengthen the joint strength between the circuit layers 102 and the light-emitting elements 110. The alignment components may include the same or similar material as the circuit layers 102, such as copper (Cu), tin (Sn), nickel (Ni), silver (Ag), gold (Au), titanium (Ti), molybdenum (Mo), tungsten (W), aluminum (Al), other suitable conductive materials, or a combination thereof, but it is not limited thereto. According to some embodiments, the alignment components may be additional conductive bumps (under bump metallization, UBM) disposed above the circuit layers 102, but is not limited thereto.

In some embodiments, as shown in FIG. 1C, an element structure 106 and a control unit 108 in the element structure 106 are disposed in the insulating structure 104. As shown in FIG. 1C, the control unit 108 includes a gate 108G electrically connected to a semiconductor layer 108C and an interconnect structure 109. The control unit 108 may be an element for controlling a light-emitting element, such as a control element including a transistor, but is not limited thereto. In some embodiments, the control unit may include a thin film transistor (TFT) element. The thin film transistor may include low-temperature silicon semiconductors, polysilicon semiconductors, oxide semiconductors or a combination thereof, but is not limited thereto. The semiconductor layer 108C may include materials suitable for use as a channel layer, such as amorphous silicon, polysilicon, indium gallium zinc oxide (IGZO), other suitable semiconductor materials, or a combination thereof, but it is not limited thereto. The material of the gate 108G and the interconnection structure 109 may be similar to that of the circuit layers 102, but is not limited thereto.

Depending on the application of the electronic device 10, such as a display, a light-emitting device, a backlight module, a solar cell, a sensing device, and a high frequency device, the light-emitting elements 110 may be various elements for emitting light. For example, the light-emitting elements 110 may include, for example, a mini light-emitting diode (mini LED), a micro light-emitting diode (micro LED), an organic light-emitting diode (OLED), other suitable light-emitting elements, or a combination thereof, but it is not limited thereto. For example, in the following embodiments, the light-emitting elements 110 of light-emitting diode elements will be used for illustration. The light-emitting elements 110 may have electrical connection parts 112 and 114 respectively electrically connected to semiconductor layers of different conductivity types (e.g., n-type and p-type). In some embodiments, the electrical connection parts 112 and 114 are electrically connected to the substrate 100, such as the circuit layers 102 of the substrate 100, through bonding members 116. In some embodiments, the electrical connection parts 112 and 114 are aligned to the alignment components of the substrate 100 to ensure that the light-emitting elements 110 are disposed at designated positions above the substrate 100.

The materials of the electrical connection parts 112 and 114 include Cu, Sn, Ni, Ag, Au, Ti, Mo, W, other suitable conductive materials, or a combination thereof, but are not limited thereto. The material of the bonding members 116 may include, for example, Au, Sn, Al, Cu, Ti, Ag, Ga, other suitable metals, or a combination thereof, but is not limited thereto. In some embodiments, the material of the bonding members 116 includes a mixture of organic materials and particles of the aforementioned metals. In some embodiments, there is a diffusion region between the electrical connection parts 112, 114 and the bonding members 116, and the diffusion region includes elements from the electrical connection parts 112, 114 and the bonding members 116.

Next, referring to FIGS. 1A and 1B, the protective layer 120 may be disposed to surround the light-emitting elements 110 and the substrate 100. In detail, the protective layer 120 may be disposed to surround the connecting element. That is, the protective layer 120 may contact the side surface S of the connecting element. According to some embodiments, the protective layer 120 may contact the upper surface of the connecting element, but is not limited thereto. In some embodiments, the transparent layer 124 is disposed on the substrate 100 and surrounds the light-emitting elements 110. In some embodiments, as shown in FIGS. 1A and 1B, the light-emitting elements 110 are separated from one another by the opaque layer 122. Adjacent light-emitting elements 110 may emit light of the same color or different colors, such as white light, red light, green light or blue light, but it is not limited thereto. Through the above configuration, light mixing of different colors can be avoided, thereby improving the display quality, but it is not limited thereto. One light-emitting element 110 may be regarded as one sub-pixel unit of the display device, but it is not limited thereto. At least a portion of the transparent layer 124 is respectively disposed in the openings O of the opaque layer 122 and covers the plurality of light-emitting elements 110. In detail to said, a height of the opaque layer 122 is higher than a height of the light-emitting elements 110. The plurality of light-emitting elements 110 may be disposed in different transparent portions 124P to directly contact the transparent layer 124. Through the above arrangement, the bonding ability between the light-emitting elements 110 and the transparent layer 124 can be improved, thereby improving the reliability of the electronic device 10, but it is not limited thereto.

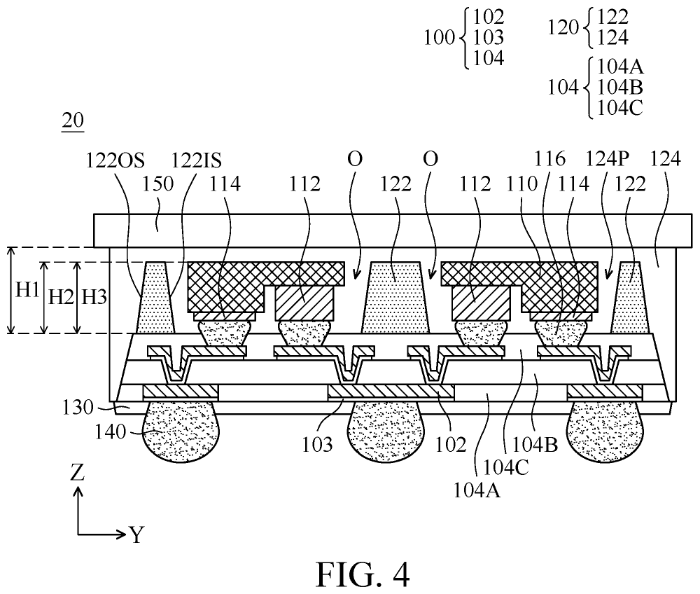

In some embodiments, as shown in FIG. 1A, the protective layer 120 directly contacts the side surface of the substrate 100, or the protective layer 120 directly contacts the side surface S of the connecting element. Through the above arrangement, the bonding ability between the substrate 100 and the protective layer 120 can be improved, thereby improving the reliability of the electronic device 10, but it is not limited thereto. In some embodiments, as shown in FIG. 1A, the opaque layer 122 is in direct contact with the side surface of the substrate 100, or the opaque layer 122 is in direct contact with the side surface S of the connecting element. Since the opaque layer 122 is in direct contact with the side surface of the substrate 100, the influence from external light or ambient light can be reduced, but it is not limited thereto. In other embodiments, for example, in the subsequent electronic device 20 in FIG. 4, the transparent layer 124 may also be in direct contact with the side surface of the substrate 100 or the transparent layer 124 may be in direct contact with the side surface of the connecting element. Although the upper surfaces of the opaque layer 122 and the transparent layer 124 are substantially equal in height in the embodiment of FIG. 1A, the present disclosure is not limited thereto. In other embodiments, a portion of the transparent layer may also extend above the opaque layer 122. According to some embodiments, the opaque layer 122 contacts the upper surface of the connecting element, and the side surface of the opaque layer 122 has an angle θ2 with the upper surface of the connecting element, and the angle θ2 may be greater than or equal to 60 degrees and less than or equal to 90 degrees. Through the above configuration, the bonding ability between the connecting element and the opaque layer 122 can be improved, or the quality of the emitted light of the light-emitting elements can be optimized, thereby improving the reliability or quality of the electronic device 10, but it is not limited thereto.

By forming the protective layer 120, moisture can be prevented from affecting the performance of the light-emitting elements 110 or the substrate 100. In addition, since the protective layer 110 may include the opaque layer 122 and the transparent layer 124 of different materials at the same time, while the light from the light-emitting elements 110 pass through the transparent layer 124, it can be shielded by the opaque layer 122. In this way, crosstalk between adjacent light-emitting elements 110 can be reduced. By modularizing the light-emitting elements 110 with such protective layer 120 and performing mass transfer, the times of transfer can be reduced, or the manufacturing cost and time of the electronic device can be reduced.

In some embodiments, along the Z direction, the first height H1 from the upper surface of the transparent layer 124 to the upper surface of the substrate 100 and the second height H2 from the upper surface of the opaque layer 122 to the upper surface of the substrate 100 have the following relationship: 0.9×H2<H1<1.1×H2. In some embodiments, the second height H2 from the upper surface of the opaque layer 122 to the upper surface of the substrate 100 has the following relationship with the third height H3 from the upper surface of the light-emitting elements 110 to the upper surface of the substrate 100: H2≥H3. Through the above-mentioned design, it is possible to reduce the mixing of light from adjacent light-emitting elements to affect the display quality and improve the reliability of the electronic device, but it is not limited thereto.

The material of the opaque layer 122 may include, for example, black resin, gray resin, white resin, metal or other suitable materials, or a combination thereof, but is not limited thereto. The material of the transparent layer 124 may include, for example, silicone resin, epoxy resin, acrylic resin, other suitable materials, or a combination thereof, but is not limited thereto. According to some embodiments, along a direction perpendicular to the Z direction (for example, the Y direction), the openings O have a width W1, and the opaque layer 122 has a width W2, wherein W1 may be greater than or equal to W2 to avoid affecting the aperture ratio, but not the limit.

In some embodiments, the electronic device 10 further includes a stress adjustment layer 130 disposed on the side of the substrate 100 that is opposite the light-emitting elements 110. As shown in FIG. 1A, the stress adjustment layer 130 may cover the bottom surface of the substrate 100. By disposing the stress adjustment layer 130 on the substrate 100, during the deposition of features on the other side of the substrate 100 (such as the subsequently formed bonding terminals 140 or other electronic elements electrically connected to the substrate 100 through the bonding terminals 140, etc.), the stress balance of the substrate 100 is further maintained to avoid warping of the substrate 100. In some embodiments, the coefficient of thermal expansion of the stress adjustment layer 130 is close to that of the insulating structure 104 in the substrate 100. The thermal expansion coefficient of the stress adjustment layer 130 may be greater than or equal to 1 ppm/° C. and less than or equal to 15 ppm/° C. The material of the stress adjustment layer 130 may include silicon nitride, silicon oxide, silicon oxynitride, aluminum oxide, other suitable insulating materials, or a combination thereof, but is not limited thereto. The thickness of the stress adjustment layer 130 may be between about 500 nanometers and about 3000 nanometers (500 nm≤thickness of the stress adjustment layer 130≤3000 nm).

In some embodiments, the electronic device 10 further includes multiple bonding terminals 140 disposed on the side of the substrate 100 that is opposite the light-emitting elements 110, and each bonding terminal 140 is electrically connected to at least one of the light-emitting elements 110. More specifically, each bonding terminal 140 can be electrically connected to at least one light-emitting element 110 through the circuit layers 102 in the substrate 100. By forming the bonding terminals 140, the resulted electronic device 10 can be bonded to an external circuit. According to some embodiments, the external circuit may be, for example, a printed circuit board, a flexible printed circuit board, a driving circuit, or a combination thereof. According to some embodiments, the seed layer 103 between the bonding terminals 140 and the circuit layers 102 may be omitted.

Referring to FIG. 1B, the electronic device 10 may include an array of light-emitting elements 110, and each light-emitting element 110 in the array may be surrounded by a transparent portion 124P. For example, as shown in FIG. 1B, the electronic device 10 may include an array of pixels 10P, and each pixel 10P may include three adjacent light-emitting elements 110, but the number and arrangement of the light-emitting elements 110 in each pixel 10P are not limited to this. In a specific embodiment, the light-emitting elements 110 are light-emitting diode elements, and each pixel 10P may include light-emitting elements 110 for emitting red light, green light, and blue light respectively, but is not limited thereto. Those skilled in the art may adjust the arrangement of the light-emitting elements 110 and the wavelength of light emitted according to the design requirements of the electronic device.

Each bonding terminal 140 of the electronic device 10 may be electrically connected to the light-emitting elements 110 from the same or different pixels 10P at the same time. More specifically, depending on the arrangement of the light-emitting elements 110 and the positions of the electrical connection parts 112, 114 of each light-emitting element 110, those skilled in the art may adjust the configuration of the bonding terminals 140 to be electrically connected to any one or more of the light-emitting elements 110. For example, referring to FIG. 1A, the bonding terminal 140 located in the middle may be electrically connected to the electrical connection parts 112 of two light-emitting elements 110 at the same time, wherein the electrical connection parts 112 may be electrically connected to semiconducting layers of the same conductivity type (e.g. n-type) of the light-emitting elements 110. By providing the bonding terminals 140 electrically connected to multiple light-emitting elements 110 at the same time, the number of the bonding terminals 140 can be reduced, thereby reducing the complexity of the circuit of the electronic device 10.

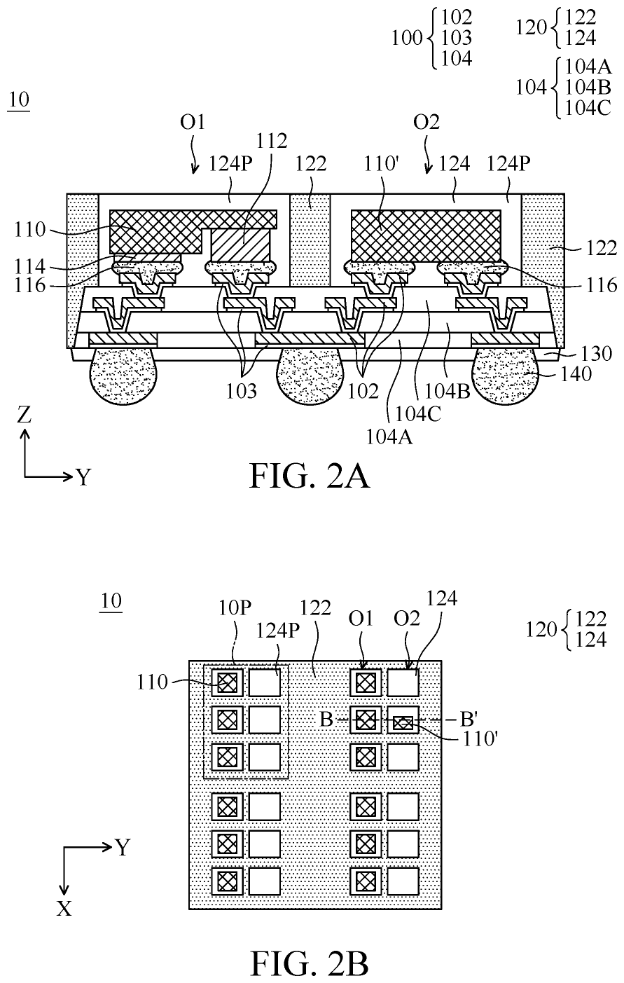

FIGS. 2A and 2B illustrate a cross-sectional view and a top view of the electronic device respectively, in accordance with some embodiments of the present disclosure, wherein FIG. 2A is the cross-sectional view on the direction of the section line BB′ of FIG. 1B. The difference from the embodiment in FIGS. 1A and 1B is that in the embodiment in FIGS. 2A and 2B, there is no light-emitting element 110 in at least one transparent portion 124P. In some embodiments, there may be no light-emitting element 110 in a transparent portion 124P, and such transparent portion 124P may be disposed adjacent to the transparent portion 124P covering the light-emitting element 110. For example, as shown in FIG. 2B, in each pixel 10P, there may be a light-emitting element 110 in the transparent portion 124P in the opening O1 of the opaque layer 122, and there may not be any light-emitting element 110 in the transparent portion 124P in the opening O2.

It should be understood that the transparent portion 124P (or the opening O2) without any light-emitting element 110 inside may also be referred to as a redundant position. The redundant position can be used for repair of the electronic devices. For example, if the light-emitting element 110 in the adjacent transparent portion 124P fails, the transparent portion 124P at the redundant position may be removed, and then an additional light-emitting element 110 may be placed in the redundant position to repair the electronic device. In FIGS. 2A and 2B, in addition to placing light-emitting elements, the redundant positions can also be used for placing integrated circuits (ICs), capacitors, varactors, sensors, diode, photo diode, other suitable electronic elements 110′, or a combination thereof, but they are not limited to this.

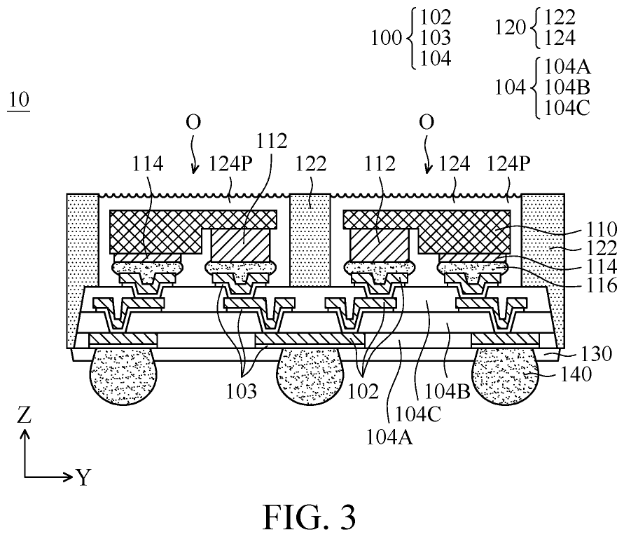

FIG. 3 illustrates a cross-sectional view of the electronic device 10, in accordance with some embodiments of the present disclosure. In some embodiments, the upper surface of the transparent layer 124 may have a rough profile. For example, the roughness (R_{z}) of the upper surface of the transparent layer 124 may be in the range of 0.02 μm-50 μm, in the range of 0.1 μm-30 μm, or in the range of 1 μm-20 μm. It should be understood that the above-mentioned roughness (R_{z}) of the upper surface may be defined as a value obtained by taking the local roughness of ten points on the upper surface with an instrument such as a scanning electron microscope and calculating according to the following formula:

$${R}_{z} = \frac{1}{5} {\sum }_{t = 1}^{5} {R}_{p t} - {R}_{vt}$$

where Rₚₜ is the local roughness at the protrusion and Rᵥₜ is the local roughness at the recess. In some embodiments, the roughness of the upper surface of the transparent layer 124 is greater than the roughness of the upper surface of the opaque layer 122, but is not limited thereto. The transparent layer 124 with a rough upper surface can diffuse the light from the light-emitting elements 110, making the light soft and uniform.

FIG. 4 illustrates a cross-sectional view of an electronic device 20, in accordance with some other embodiments of the present disclosure. The difference from the above electronic device 10 is that the electronic device 20 further includes a cover substrate 150 disposed on the protective layer 120, and a portion of the protective layer 120 may be disposed between the cover substrate 150 and the light-emitting elements 110. In some embodiments, a portion of the transparent layer 124 is disposed between the cover substrate 150 and the opaque layer 122. For example, in a cross-sectional view, the transparent layer 124 may extend between the cover substrate 150 and the opaque layer 122 along a direction perpendicular to the Z direction, so the transparent layer 124 may have an extending portion extending between two adjacent openings O continuously, and this extending portion also extends on the portion of the opaque layer 122 between two adjacent openings O. By disposing the cover substrate 150 on the protective layer 120, it is possible to further prevent moisture from entering the space around the light-emitting elements 110. According to some embodiments, when the hardness of the covering substrate 150 is greater than or equal to the hardness of the protective layer 120, for example, damage to the light-emitting elements 110 can be avoided when external objects collide with the electronic device 10, but it is not limited thereto.

The material of the cover substrate 150 may include such as glass, polyimide (PI), polyethylene terephthalate (PET), other suitable materials or a combination thereof, but is not limited thereto.

In some embodiments, as shown in FIG. 4, the transparent layer 124 is in direct contact with the side surface of the substrate 100. That is, the transparent layer 124 may at least directly contact the side surface of the connecting element. In addition, the transparent layer 124 may cover the opaque layer 122. In some embodiments, as shown in FIG. 4, the opaque layer 122 includes an inner sidewall 122IS close to the light-emitting element 110s and an outer sidewall 122OS away from the light-emitting elements 110, and the transparent layer 124 may be in direct contact with the outer sidewall 122OS of the opaque layer 122. In FIG. 4, although the bonding members 116 are disposed in the openings of the insulating structure 104 to be electrically connected to the flat upper surface of the circuit layer 102, the present disclosure is not limited thereto. In some embodiments, the bonding members 116 are disposed on the alignment components to electrically connect the light-emitting elements 110 and the substrate 100.

In some embodiments, along the Z direction, the first height H1 from the upper surface of the transparent layer 124 to the upper surface of the substrate 100 and the second height H2 from the upper surface of the opaque layer 122 to the upper surface of the substrate 100 have the following relationship: 0.9×H2<H1<1.1×H2. In addition, although the top surfaces of the light-emitting elements 110 and the opaque layer 122 are shown as substantially equal in height in FIG. 4, the present disclosure is not limited thereto. In some embodiments, the second height H2 from the upper surface of the opaque layer 122 to the upper surface of the substrate 100 has the following relationship with the third height H3 from the upper surface of the light-emitting elements 110 to the upper surface of the substrate 100: H2≥H3. According to the above design, the crosstalk between adjacent light-emitting elements 110 can be reduced or the light can be mixed evenly, or the display quality can be improved, but it is not limited thereto.

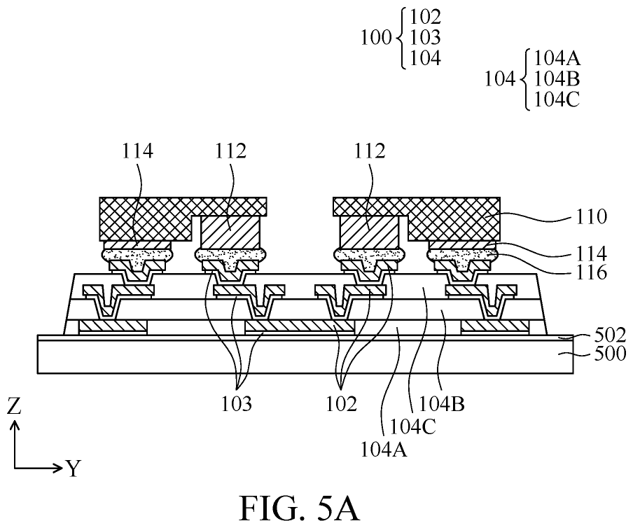

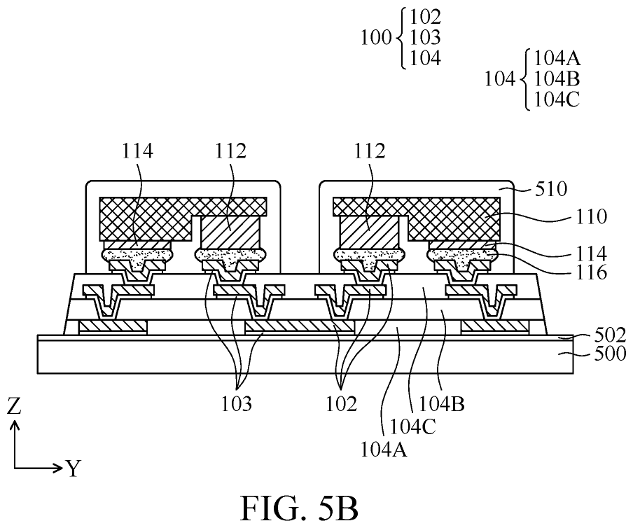

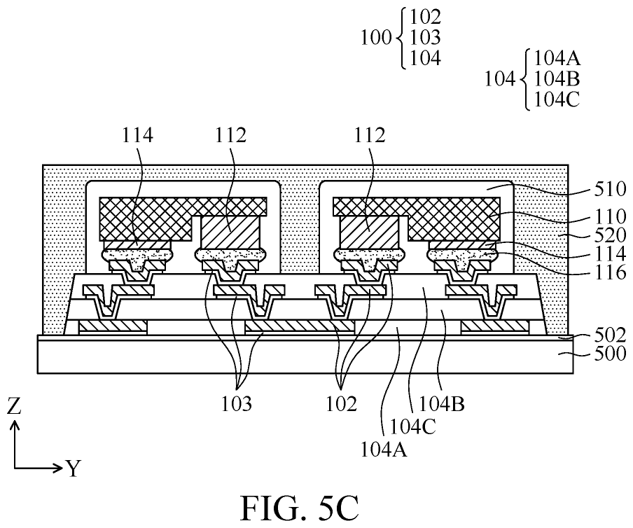

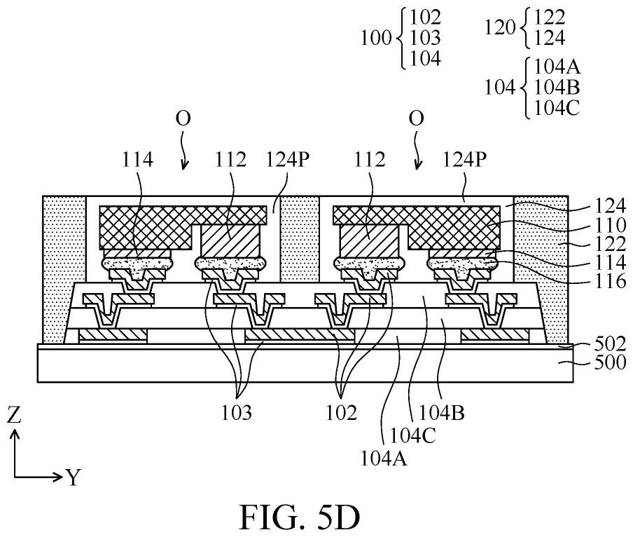

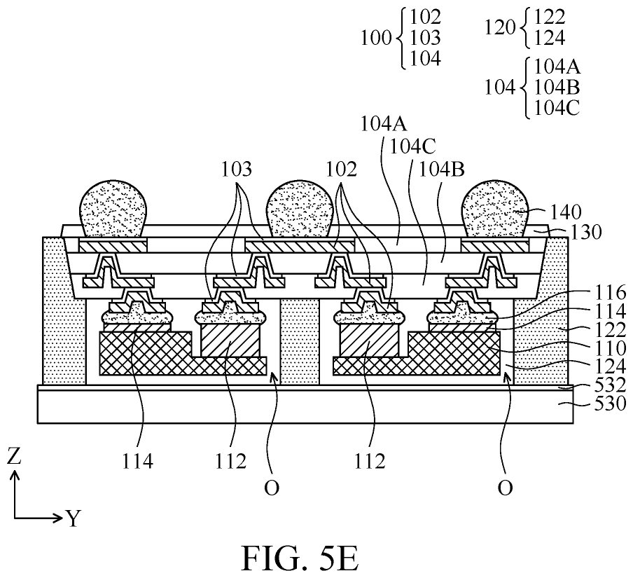

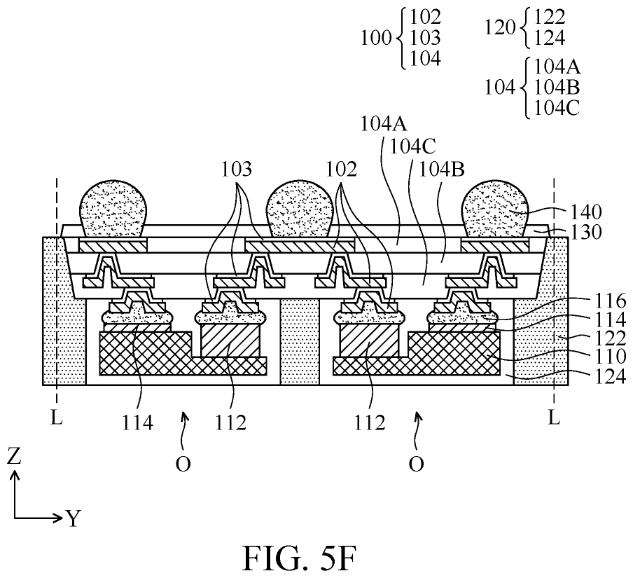

FIGS. 5A-5F illustrate cross-sectional views of an electronic device in various stages of a manufacturing process, in accordance with some embodiments of the present disclosure.

Referring to FIG. 5A, the substrate 100 may be formed on a carrier board 500 first. In some embodiments, a release film 502 may be formed on the carrier board 500 before the substrate 100 is formed. By disposing the release film 502 between the carrier board 500 and the substrate 100, it is beneficial to peel off the substrate 100 from the carrier board 500 in subsequent processes. According to some embodiments, the release film 502 may be omitted.

The present disclosure does not specifically limit the material of the carrier board 500. For example, the material of the carrier board 500 may include hard or soft materials, such as glass, ceramics, polyimide (PI), polyethylene terephthalate (PET), steel plate, silicon base, other suitable materials or a combination thereof, but it is not limited thereto. The material of the release film 502 may include polyethylene (PE), PET, polycarbonate (PC), polystyrene (PS), poly methyl methacrylate (PMMA), poly vinyl chloride (PVC), other suitable materials or a combination thereof, but it is not limited thereto.

The formation of the substrate 100 may include forming multiple circuit layers 102 and an insulating structure 104 surrounding the circuit layers 102. The process for forming the circuit layers 102 may include depositing conductive materials on the carrier board 500 (or the release film 502) and on the insulating layers (e.g., the insulating layers 104A, 104B, and 104C) in the insulating structure 104. For example, the process for depositing the conductive material in the circuit layers 102 may include, for example, physical vapor deposition (PVD), chemical vapor deposition (CVD), atomic layer deposition (ALD), electroplating, chemical plating, electroless plating, thin film process, patterning process, other suitable processes, or a combination thereof, but it is not limited thereto. The aforementioned conductive materials include, for example, Cu, Sn, Ni, Ag, Au, Ti, Mo, W, other suitable conductive materials, or a combination thereof, but are not limited thereto.

The process for forming each layer in the insulating structure 104 may include, for example, physical vapor deposition (PVD), chemical vapor deposition (CVD), atomic layer deposition (ALD), coating, bonding, curing process, thin film process, patterning process, other suitable processes, or a combination thereof, but it is not limited thereto. In some embodiments, the formation of the substrate 100 includes first depositing a seed layer 103 on the carrier board 500 (or the release film 502) and the insulating layers (such as the insulating layers 104A, 104B, and 104C) in the insulating structure 104, and then a conductive material for the circuit layers 102 is deposited on the seed layer 103. The process for depositing the seed layer 103 may be the same as or different from that for depositing the circuit layers 102.

As shown in FIG. 5A, in order to dispose the light-emitting elements 110 above the substrate 100, multiple alignment components may be formed on the substrate 100, and at least one of the alignment components is electrically connected to the light-emitting elements 110. For example, as shown in FIG. 5A, the uppermost circuit layer 102 may be multiple alignment components. In some embodiments, the alignment component may also be a conductive bump additionally disposed on the circuit layers 102 (UBM), but it is not limited thereto. The above-mentioned alignment components may be formed by forming an opening exposing a portion of the circuit layers 102 on the upper portion of the insulating structure 104 and forming a conductive material in the opening. The formation of the alignment feature may include a deposition process and a patterning process.

Deposition processes for the alignment components may include, for example, physical vapor deposition (PVD), chemical vapor deposition (CVD), atomic layer deposition (ALD), electroplating, chemical plating, electroless plating, thin film processes, other suitable processes, or a combination thereof, but it is not limited thereto. Patterning processes for the alignment components include laser or suitable lithography and/or etching processes. The lithography process may include resist coating (e.g., spin coating), soft baking, mask alignment, exposure, post-exposure bake, resist development, rinsing, drying (e.g., spin-drying and/or hard baking), other suitable lithography techniques, or a combination thereof, but it is not limited thereto. The etching process may include dry etching (for example, RIE etching), wet etching, other etching methods, or a combination thereof, but it is not limited thereto. In some embodiments, the resulted alignment components may have top portions that are higher than the upper surface of the insulating structure 104.

Next, a plurality of light-emitting elements 110 may be formed on the substrate 100. In some embodiments, the electrical connection parts 112 and 114 of the plurality of light-emitting elements 110 may be electrically connected to the circuit layers 102 of the substrate 100 by the bonding members 116. In a specific embodiment, the electrical connection parts 112 and 114 are respectively electrically connected to the above-mentioned alignment components by the bonding members 116, but it is not limited thereto.

In some embodiments, the positions where the circuit layers 102 or the alignment components are exposed from the upper surface of the substrate 100 include a position where the light-emitting element 110 is formed and a position where the light-emitting element 110 is not formed. A position where the light-emitting element 110 is not formed may be referred as a redundant position, which may be used for repair of the electronic device. For example, if a neighboring light-emitting element 110 fails, an additional light-emitting element 110 may be placed in the redundant position to repair the electronic device. In addition to placing light-emitting elements, the redundant positions may also be used for placing integrated circuits, capacitors, sensors, other suitable elements, or a combination thereof, but it is not limited thereto.

Next, referring to FIGS. 5B to 5D, a protective layer 120 is formed on the substrate 100. The protective layer 120 may include an opaque layer 122 and a transparent layer 124. As shown in FIG. 5D, the opaque layer 122 may have a plurality of openings O. The transparent layer 124 may cover the light-emitting elements 110 and has a plurality of transparent portions 124P disposed in the openings O. In some embodiments, the formation of the protective layer 120 includes forming the transparent layer 124 spaced apart from each other and covering the light-emitting elements 110 on the substrate 100, and further includes forming the opaque layer 122 on the transparent layer 124 and the substrate 100.

Referring to FIG. 5B, in some embodiments, the formation of the transparent layer 124 includes depositing a transparent material 510 covering the light-emitting elements 110 on the substrate 100. The deposition method of the transparent material 510 may include ink-jet printing, spin-on coating, other suitable deposition processes, or a combination thereof, but is not limited thereto. In some embodiments, portions of the transparent material 510 separated from each other and covering the light-emitting elements 110 may be formed on the substrate 100 by ink-jet printing, and then a curing process is performed on the transparent material 510 with a radiation source (such as an ultraviolet light source). In some other embodiments, the transparent material 510 that is continuous and covers the light-emitting elements 110 may be formed on the substrate 100 first, and then the transparent material 510 is patterned to form portions of the transparent materials 510 spaced apart from each other. Finally, the curing process is used to form the transparent material 510 for forming the transparent layer 124. The aforementioned patterning process may include suitable lithography and/or etching processes. The lithography process may include photoresist coating (e.g., spin coating), soft bake, mask alignment, exposure, post-exposure bake, photoresist development, rinsing, drying (e.g., spin dry and/or hard bake, other suitable lithography techniques, or a combination thereof, but it is not limited thereto. The etching process may include dry etching (for example, RIE etching), wet etching, other etching methods, or a combination thereof, but it is not limited thereto. In a specific embodiment, a mold may also be used to pattern the transparent material 510 that is continuous and covers the light-emitting elements 110 into separate portions. The transparent material 510 may include, for example: silicone resin, epoxy resin, acrylic resin, other suitable materials, or a combination thereof, but it is not limited thereto.

Referring next to FIG. 5C, an opaque material 520 may be deposited on the transparent material 510. The opaque material 520 may include, for example, black resin, gray resin, white resin, other suitable materials, or a combination thereof, but is not limited thereto. As shown in FIG. 5C, in some embodiments, the deposited opaque material 520 covers the transparent material 510 and the substrate 100.

Referring to FIG. 5D, a planarization process may be performed to remove part of the opaque material 520 and the transparent material 510 to form the opaque layer 122 and the transparent layer 124 respectively, and the portion of the transparent material 510 extending into the opening O of the opaque layer 122 becomes the transparent portions 124P. The planarization process may include, for example, a chemical mechanical polishing (CMP) process, other suitable planarization processes, or a combination thereof, but is not limited thereto. As shown in FIG. 5D, the planarization process can make the upper surfaces of the opaque layer 122 and the transparent layer 124 equal in height. In some embodiments, after the planarization process, a surface treatment is performed on the upper surface of at least one of the transparent portions 124P to increase the roughness of the upper surfaces of the transparent portions 124P so that the upper surfaces of the transparent portions 124P have a rough profile.

Next, referring to FIG. 5E, the upper surfaces of the opaque layer 122 and the opaque layer 124 may be transferred to the carrier board 530 and then the carrier board 500 and the release film 502 are peeled off. In some embodiments, a release film 532 may be formed on the carrier board 530 before the upper surfaces of the opaque layer 122 and the opaque layer 124 are attached to the carrier board 530. By disposing the release film 532 between the carrier board 530 and the opaque layer 122 and the opaque layer 124, it is beneficial to strip the opaque layer 122 and the opaque layer 124 from the carrier board 530 in the subsequent process.

After the carrier board 500 and the release film 502 are peeled off, a stress adjustment layer 130 may be formed on the surface of the substrate 100 and the opaque layer 122 (the upper surfaces of the substrate 100 and the opaque layer 122 in FIG. 5E). The process for depositing the stress adjustment layer 130 may include, for example, physical vapor deposition (PVD), chemical vapor deposition (CVD), atomic layer deposition (ALD), other suitable processes, or a combination thereof, but is not limited thereto. Then, bonding terminals 140 electrically connected to the circuit layers 102 may be formed on the substrate 100. In some embodiments, the formation of the bonding terminals 140 includes forming vias through the stress adjustment layer 130 using a patterning process and depositing a conductive material for the bonding terminals 140.

The above-mentioned patterning process may include suitable thin film processes including lithography and/or etching processes. The lithography process may include photoresist coating (e.g., spin coating), soft bake, mask alignment, exposure, post-exposure bake, photoresist development, rinsing, drying (e.g., spin dry and/or hard bake, other suitable lithography techniques, or a combination thereof, but it is not limited thereto. The etching process may include dry etching (e.g., RIE etching), wet etching, other etching methods, or a combination thereof, but it is not limited thereto. The deposition process of the bonding terminals 140 may include, for example, physical vapor deposition (PVD), chemical vapor deposition (CVD), atomic layer deposition (ALD), electroplating, electroless plating, printing, ball planting, other suitable processes, or a combination thereof, but not limited to this.

Next, refer to FIG. 5F. After the bonding terminals 140 are formed, the carrier board 530 and the release film 532 may be peeled off. In some embodiments, a dicing process (for example, along the dicing line L in FIG. 5F) may be performed before or after peeling off the carrier board 530 to form multiple modularized electronic devices. Depending on the design requirements of each electronic device after dicing, there may be the same, similar, or different types of light-emitting elements 110 in each opening O, or there may be no light-emitting element 110 in an opening O to form a redundant position, which is not limited in this disclosure.

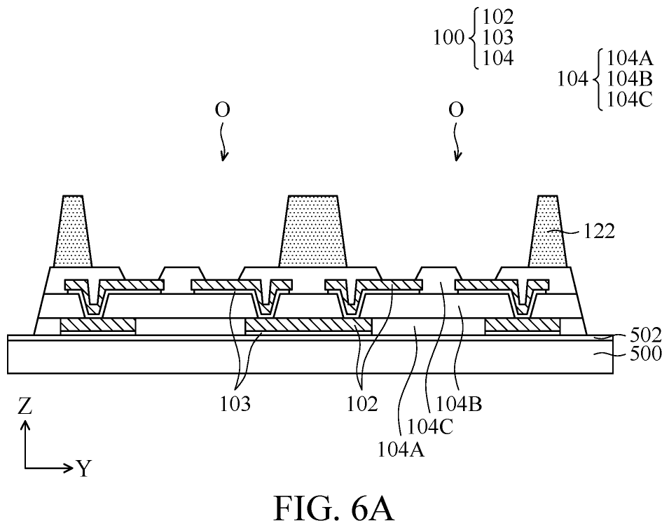

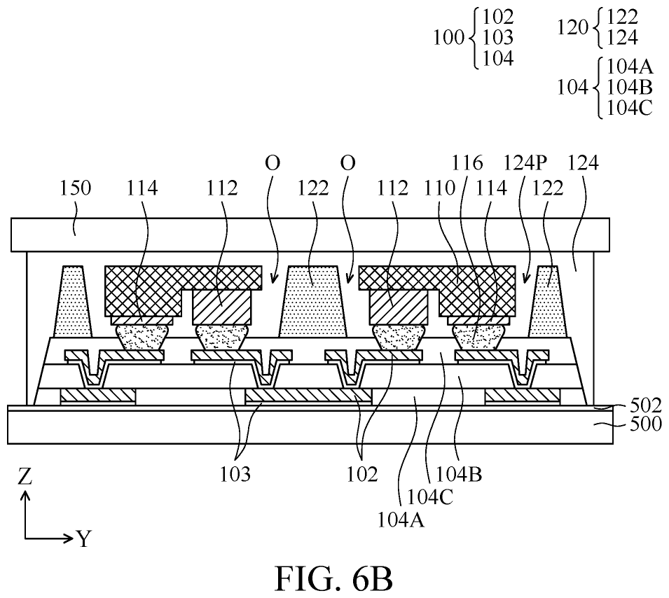

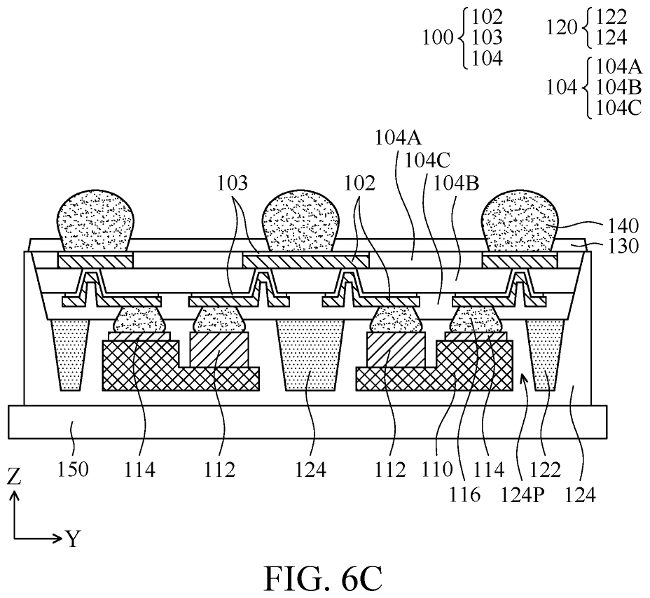

FIGS. 6A-6C illustrate cross-sectional views of an electronic device in various stages of a manufacturing process, in accordance with some other embodiments of the present disclosure.

The difference with the method of forming the electronic device corresponding to the embodiments of FIGS. 5A to 5F is that in the method of FIGS. 6A to 6C, the opaque layer 122 with openings O is formed on the substrate 100 before the light-emitting elements is formed, and the transparent layer 124 is formed after the opaque layer 122 is formed. Referring to FIG. 6A, first, the substrate 100 formed on the carrier board 500 and the release film 502 may be provided. The materials of the carrier board 500 and the release film 502 and the method of forming the substrate 100 are similar to those described in the embodiments corresponding to FIGS. 5A-5F, and the description thereof is omitted here for simplicity. As shown in FIG. 6A, the opaque layer 122 may be formed on the upper surface of the substrate 100 and expose the side surface of the substrate 100.

Next, referring to FIG. 6B, each of the light-emitting elements 110 may be formed in different openings O of the opaque layer 122. In some embodiments, the positions where the circuit layer s102 are exposed from the upper surface of the substrate 100 include the position where the light-emitting element 110 is formed and the position where the light-emitting element 110 is not formed. The position where the light-emitting element 110 is not formed may be referred to as a redundant position, which may be used for repair of the electronic device. For example, if a neighboring light-emitting element 110 fails, an additional light-emitting element 110 may be placed in the redundant position to repair the electronic device. In addition to placing light-emitting elements, the redundant positions may also be used for placing integrated circuits, sensors, other suitable elements, or a combination thereof, but it is not limited thereto.

After the light-emitting elements 110 are formed on the substrate 100, the transparent layer 124 may be formed. As shown in FIG. 6B, a cover substrate 150 may then be formed on the protective layer 120, and a portion of the protective layer 120 may be disposed between the cover substrate 150 and the light-emitting elements 110. In some embodiments, a portion of the transparent layer 124 extends between the cover substrate 150 and the opaque layer 122. For example, the transparent layer 124 may have an extending portion extending continuously between two adjacent openings O, and this extending portion also extends on the portion of the opaque layer 122 between the two adjacent openings O.

Next, referring to FIG. 6C, the entire structure may be turned over and the carrier board 500 and the release film 502 may be peeled off. Then components such as the stress adjustment layer 130 and the bonding terminals 140 may be formed on the reversed upper surfaces of the substrate 100 and the transparent layer 124. The forming method of the stress adjustment layer 130 and the bonding terminals 140 is similar to that described in the embodiments corresponding to FIGS. 5A-5F, and the description thereof is omitted here for simplicity.

In summary, the present disclosure provides an electronic device and a method for forming the same, wherein the connecting element is integrated into the electronic device and the light-emitting elements are modularly packaged with both transparent and opaque materials. By carrying out mass transfer of the light-emitting elements packaged by modularization, the number of transfers can be reduced, or the manufacturing cost and time of the electronic device can be reduced. In addition, due to the modularization of each light-emitting element by using the connecting element, the repair of failure of individual light-emitting elements becomes easier. Compared with conventional electronic devices sealed with a single encapsulation material, the electronic device of the present disclosure can reduce the manufacturing cost of the electronic device or increase the integration density.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An electronic device, comprising:
a substrate comprising a connecting element;
a plurality of light-emitting elements disposed on the substrate; and
a protective layer disposed on the substrate and comprising:
an opaque layer having a plurality of openings; and
a transparent layer covering at least one of the plurality of light-emitting elements,
wherein the protective layer surrounds the connecting element and at least a portion of the transparent layer disposed in the at least one of the plurality of openings.

2. The electronic device as claimed in claim 1, wherein the light-emitting elements are separated from one another by the opaque layer.

3. The electronic device as claimed in claim 1, wherein the opaque layer is in direct contact with a side surface of the connecting element.

4. The electronic device as claimed in claim 3, wherein the transparent layer is in direct contact with the side surface of the connecting element.

5. The electronic device as claimed in claim 1, wherein a first height H1 from an upper surface of the transparent layer to an upper surface of the substrate and a second height H2 from an upper surface of the opaque layer to the upper surface of the substrate have the following relationship: 0.9×H2<H1<1.1×H2.

6. The electronic device as claimed in claim 1, wherein a second height H2 from an upper surface of the opaque layer to the upper surface of the substrate and a third height H3 from an upper surface of the light-emitting element to the upper surface of the substrate have the following relationship: H2≥H3.

7. The electronic device as claimed in claim 1, further comprising a cover substrate disposed on the protective layer, wherein a portion of the protective layer is disposed between the cover substrate and the light-emitting elements.

8. The electronic device as claimed in claim 1, wherein a portion of the transparent layer is disposed between the cover substrate and the opaque layer.

9. The electronic device as claimed in claim 1, further comprising a stress adjustment layer disposed on a side of the substrate opposite to the light-emitting element.

10. The electronic device as claimed in claim 1, wherein the connecting element comprises circuit layers electrically connected to each other and an insulating structure surrounding the circuit layers.

11. The electronic device as claimed in claim 1, wherein the substrate further comprises:
multiple alignment components disposed on the substrate,
wherein at least one of the alignment components is electrically connected to the light-emitting elements.

12. The electronic device as claimed in claim 1, further comprising multiple bonding terminals disposed on a side of the substrate opposite the light-emitting elements, wherein each of the bonding terminals is electrically connected to at least one of the light-emitting elements.

13. The electronic device as claimed in claim 1, wherein a roughness of an upper surface of the transparent layer is greater than a roughness of an upper surface of the opaque layer.

14. A manufacturing method of an electronic device, comprising:
providing a plurality of light-emitting elements on a substrate comprising a connecting element; and
providing a protective layer on the substrate, wherein the protective layer comprises:
an opaque layer having a plurality of openings; and
a transparent layer covering at least one of the plurality of light-emitting elements,
wherein the protective layer surrounds the connecting element and at least a portion of the transparent layer disposed in the at least one of the plurality of openings.

15. The manufacturing method as claimed in claim 14, further comprising:
depositing a transparent material on the substrate to form the transparent layer; and
providing the opaque layer on the substrate and covering the transparent layer.

16. The manufacturing method as claimed in claim 15, further comprising performing a patterning process on a transparent material to form the transparent layer.

17. The manufacturing method as claimed in claim 14, further comprising:
providing the opaque layer having a plurality of openings on the substrate before forming the light-emitting elements; and
providing the transparent layer after forming the opaque layer.

18. The manufacturing method as claimed in claim 17, wherein each of the light-emitting elements is formed in a different one of the openings of the opaque layer.

19. The manufacturing method as claimed in claim 17, further comprising performing a planarization process so that upper surfaces of the opaque layer and the transparent layer are equal in height.

20. The method as claimed in claim 17, further comprising performing a surface treatment on an upper surface of the transparent layer.
